(19) United States
(12) Patent Application Publication
(10) Pub. No.: US 2002/0109174 A1
(43) Pub. Date: Aug. 15, 2002

(54) Pull-down transistor

(76) Inventors: Chi-Horn Pai, Taipei City (TW); Chih-Yuan Hsiao, Feng-Shan City (TW)

Correspondence Address: POWELL, GOLDSTEIN, FRAZER & MURPHY LLP, P.O. BOX 97233, WASHINGTON, DC, 20090-7233, US

(21) Appl. No.: 09/783,846

(22) Filed: Feb. 15, 2001

(51) Int. Cl. H01L 21/336

(52) U.S. Cl. 257/300

(57) ABSTRACT

The present invention provides an asymmetric pull-down transistor in a semiconductor device. The transistor comprises a substrate, a drain region in the substrate, a source region in the substrate wherein the source region is spaced from the drain region by a channel region and extended into a portion of the channel region, a gate structure above the channel region, and a spacer at a sidewall of the gate structure. A method comprises providing a substrate, forming a gate structure on the substrate, forming a mask covering the partial gate structure and the partial substrate. Next, the gate structure and the mask are used as implanting mask and the first ions are tilted implanted into the substrate to form a source region and a drain region. The source region is extended into the partial channel. Then the mask is removed and a spacer is formed at a sidewall of the gate structure.

### BACKGROUND OF THE INVENTION

1. Field of the Invention

The invention relates to a transistor structure, and more particularly to an asymmetric pull down transistor applied in a SRAM circuit.

2. Description of the Prior Art

There is a problem of large leakage current in a low power static random access memory (SRAM) cell, especially in case the thickness of the gate is very thin. In U.S. Pat. No. 5,629,220 discloses a process forming a pull down transistor of an SRAM semiconductor device and illustrates the process from FIG. 1A to FIG. 1C.

As depicted in FIG. 1A, a p-type substrate 120 is provided and thereon a gate oxide layer 119 is formed. A gate structure 121 made of polysilicon is then formed on the gate oxide layer 119. Next, a photoresist mask 122 covers a portion of the gate structure 121 and the gate oxide layer 119 for implantation of n-type implants 123 into a source region 127 and a drain region 128. The drain region 128 is offset to the gate structure 121 by the photoresist mask 122 which covers the part of the p-type substrate 120.

Next, a silicon oxide (not shown) is conformal formed on the gate structure 121 and the exposed surface of the gate oxide 119. Then the silicon oxide is etched for forming spacers 125 and 126 at the sidewall of the gate structure 121, shown in FIG. 1B. Next, as shown in FIG. 1C, n-type implants 131 are blanket implanted into the p-type substrate 120. Thus, a lightly doped region 129 with n-type implants 131 underlies the source region 127 and at the side of the spacer 125. Similarly, another lightly doped region 130 with n-type implants 131 underlies the drain region 128. To be specific, a portion of the lightly doped region 130 is adjacent to the top surface of the p-type substrate 120.

However, there is still high channel sheet resistance existed in the portion of the lightly doped region 130 adjacent to the top surface of the p-type substrate 120, that may cause a semiconductor device with such design can't be operated under a condition of low power.

### SUMMARY OF THE INVENTION

It is an object of the present invention to provide a method and a structure of reducing a drain side sheet resistance in a SRAM semiconductor device. The formation of a heavily doped region adjacent to the corner of a drain region can reduce the drain side sheet resistance.

It is another object of the present invention to provide a method and a structure of preventing leakage current in the pull down transistor of a SRAM cell. The portion of a source region is prolonged to a region blow a gate structure to raise threshold voltage.

In the present invention, an asymmetric pull-down transistor in a semiconductor device. The transistor comprises a substrate, a drain region in the substrate, a source region in the substrate wherein the source region is spaced from the drain region by a channel region and extended into a portion of the channel region, a gate structure above the channel region, and a spacer at a sidewall of the gate structure. A method comprises providing a substrate, forming a gate structure on the substrate, forming a mask covering the partial gate structure and the partial substrate. Next, the gate structure and the mask are used as implanting mask and the first ions are tilted implanted into the substrate to form a source region and a drain region. The source region is extended into the partial channel. Then the mask is removed and a spacer is formed at a sidewall of the gate structure.

### BRIEF DESCRIPTION OF THE DRAWINGS

A better understanding of the invention may be derived by reading the following detailed description with reference to the accompanying drawing wherein:

FIGS. 1A-1C are a series of cross-sectional schematic diagrams illustrating a MOSFET transistor device adapted for use in a SRAM circuit in accordance with the prior art; and

FIGS. 2A-2E are a series of cross-sectional schematic diagrams illustrating a MOSFET transistor device adapted for use in a SRAM circuit in accordance with the present invention.

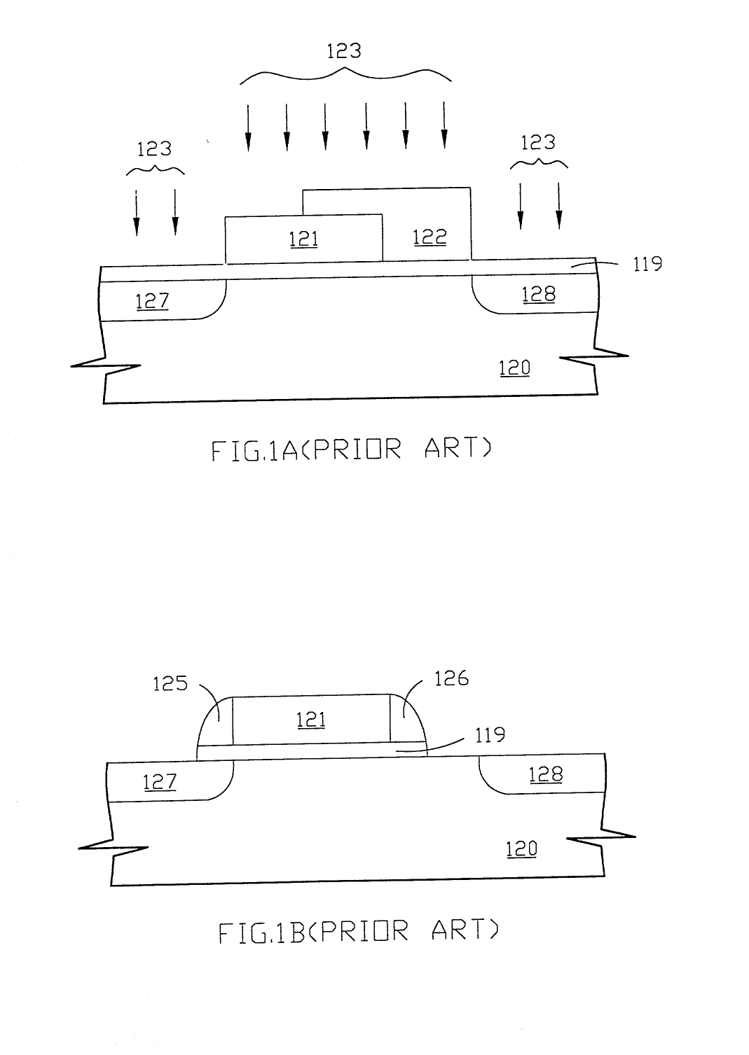

### DESCRIPTION OF THE PREFERRED EMBODIMENT

The semiconductor devices of the present invention are applicable to a board range of semiconductor devices and can be fabricated from a variety of semiconductor materials. While the invention is described in terms of a single preferred embodiment, those skilled in the art will recognize that many steps described below can be altered without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarify of illustration and should not be interpreted in a limiting sense. Accordingly, these regions will have dimensions, including length, width and depth, when fabricated in an actual device.

In the present invention, an asymmetric pull-down transistor in a semiconductor device comprises a substrate, a drain region and a source region in the substrate. The source region is spaced from the drain region by a channel region and extended into a portion of the channel region. The asymmetric pull-down transistor further comprises a gate structure above the channel region, a first lightly doped region lay under the source region and beside the channel region wherein the first lightly doped region has dopant concentration lighter than the source region does. The second lightly doped region is underlay the drain region and between the drain region and the channel region. The second lightly doped region has dopant concentration lighter than the drain region does. A method comprises providing a substrate, forming a gate structure on the substrate, forming a mask covering the partial gate structure and the partial substrate. Next, the gate structure and the mask are used as implanting mask and the first ions are tilted implanted into the substrate to form a source region and a drain region. The source region is extended into the partial channel. Then the mask is removed and a spacer is formed at a sidewall of the gate structure.

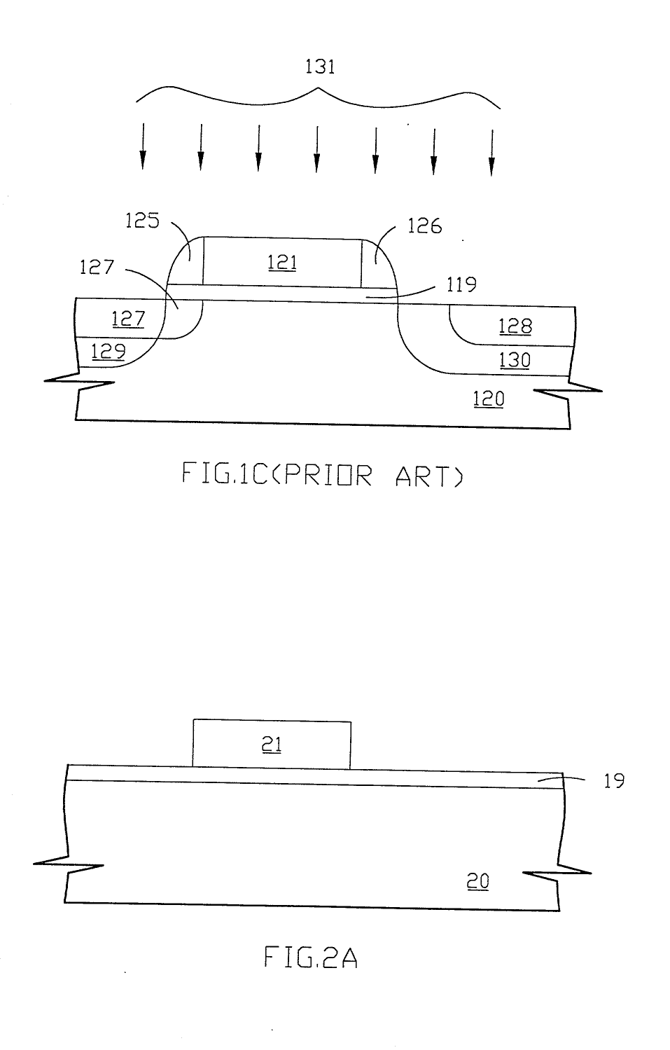

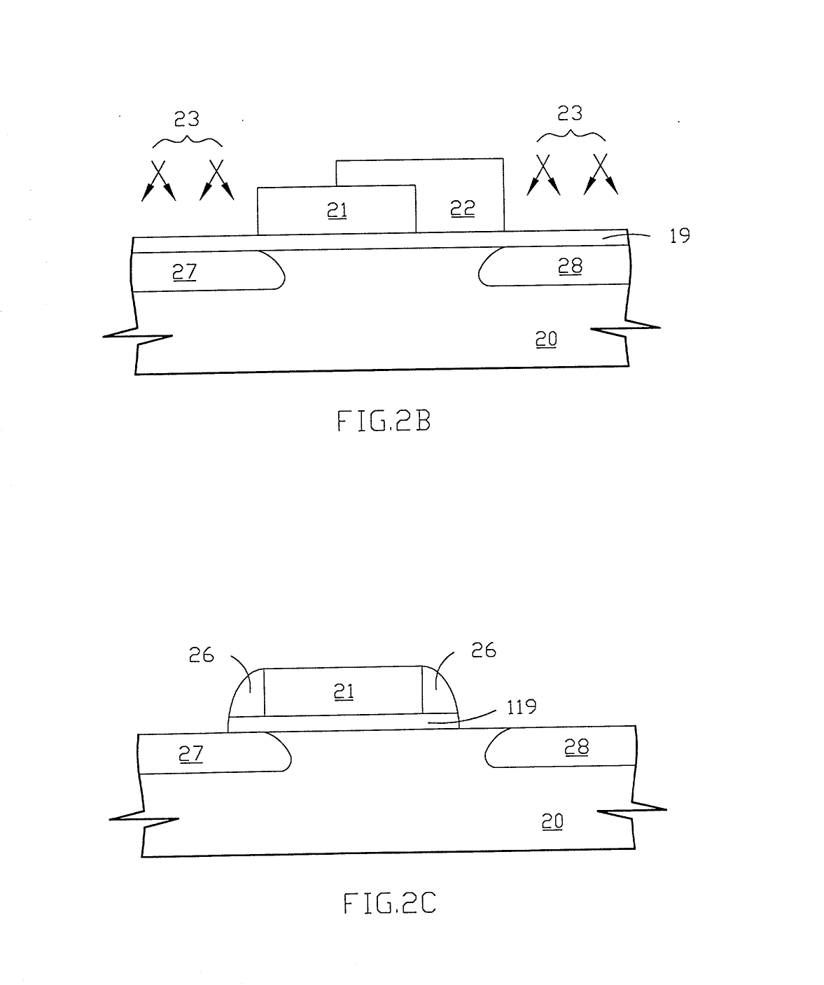

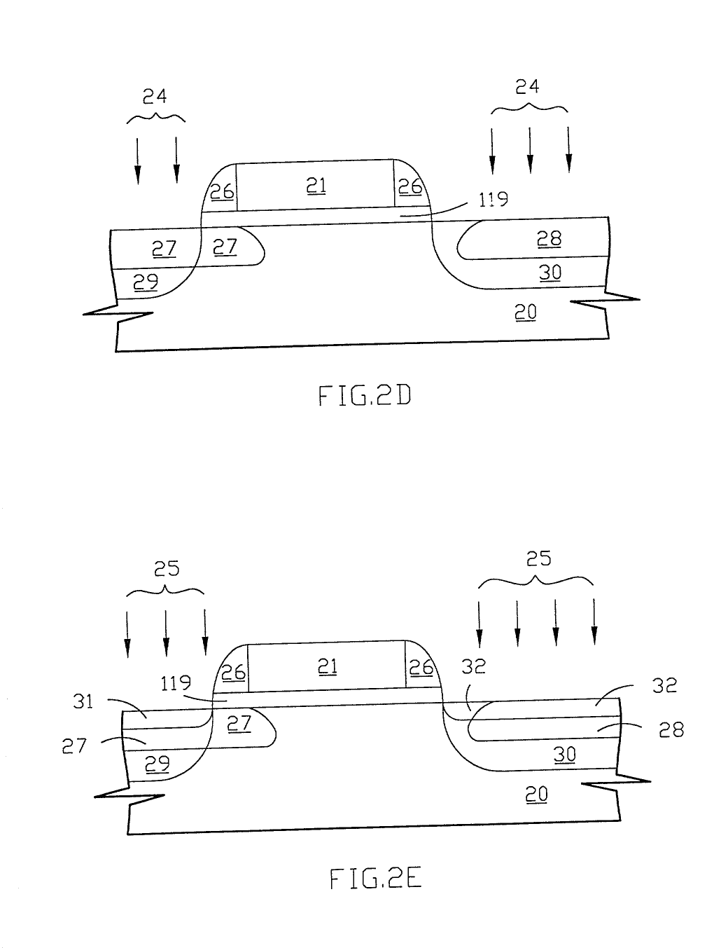

One embodiment of the present invention is depicted in FIGS. 2A-2E. First referring to FIG. 2A, a substrate 20 is provided and thereon a gate oxide layer 19 is formed. Next, a gate structure 21 is formed on the gate oxide layer 19 by any suitable method. In the embodiment, the substrate 20 can be made of silicon doped with p-type ions, such as boron. Alternatively, the substrate 20 also can be composed of n-type material and a p-well may be formed in the substrate 20 for an n-type device to be made subsequently. On the other hand, the gate oxide layer 19 may be formed by passing an oxygen rich gas over the surface of the substrate 20. The gate structure 19 comprises a heavily doped layer of polysilicon by the suitable methods, such as deposition.

Next, as one key step of the present invention shown in FIG. 2B, a photoresist mask 22 covers the portion of the gate structure 21 and the top surface of the gate oxide layer 19 adjacent to one side of the gate structure 21. Then n-type ions 23, such as arsenic ions, are implanted into the substrate 20 of both sides of the gate structure 21 to form a source region 27 and a drain region 28. To be specific, the implantation of n-type ions 23 is implemented by intersecting and tilting incident direction instead of conventional vertical to the surface of the substrate 20. One purpose of the tilted implantation is to extend the source region 27 to the region of the substrate 20 underlay the gate structure 21 and the drain region 28 to the region of the substrate 20 underlay the photoresist mask 22. Furthermore, the channel length between the source region 27 and the drain region 28 is shortened because of the extended portions of both the source region 27 and the drain region 28. In the embodiment, the tilted angle for the implantation of the n-type ions 23 is about from 10 to 20 degree from the vertical direction to the surface of the substrate 20. Of course, the tilted angle is adjustable and dependent on the requirement of a semiconductor device. Furthermore, the dosage of ions 23 is about from 1E14 to 1E15 atoms/cm², and the energy is about from 30 to 60 keV.

Next, the photoresist mask 22 is first removed by the conventional method and then a silicon dioxide layer (not shown) is deposited on the gate oxide layer 19 and the gate structure 21. The silicon dioxide layer is formed by suitable deposition, such as chemical vapor deposition (CVD). Then the silicon dioxide layer is etched to form spacer 26 at the sidewall of the gate structure 21, shown in FIG. 2C. To be specific, the drain region 28 and the gate structure 21 including the gate oxide layer 19 are separated by the substrate 20, while the source region 27 is adjacent to the gate oxide layer 19 of the gate structure 21.

As depicted in FIG. 2D, n-type ions 24, such as phosphorous ions, are parallel implanted into the substrate 20, the source region 27, and the drain region 28 to form lightly doped regions 29 and 30. With adjustment of implantation dosage and energy, the lightly doped region 29 is lay under the portion of the source region 27 and the lightly doped region 30 is underlay the drain region 28. In the embodiment, the dosage for forming the lightly doped regions is about from 1E14 to 1E15 atoms/cm², and the energy is about from 60 to 80 keV. To be specific, the portion of the lightly doped region 30 is between the gate oxide layer 19 of the gate structure 21 and the drain region 28. That is, the portion of the lightly doped region 30 is lay under the surface of the substrate 30.

Subsequently, shown in FIG. 2E, another n-type ions 25 are parallel implanted into the source region 27 and the drain region 28 to form heavily doped regions 31 and 32. By adjusting operation condition and parameters, such as implantation energy, the heavily doped regions 31 and 32 are shallower than the source region 27 and the drain region 28. In the embodiment, the dosage of ions 25 is about from 1E14 to 1E15 atoms/cm², and the energy is about from 15 to 30 keV. The portion of the heavily doped region 32 is between the top surface of the substrate 20 and the lightly doped region 30. With the existence of the heavily doped region 32 between the top surface of the substrate 20 and the lightly doped region 30, the drain side sheet resistance may be reduced. On the other hand, because the prolongation of the source region 27 underlay the region of the gate structure 21, threshold voltage may be raised and sub-threshold voltage may be reduced to decrease leakage current.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An asymmetric pull-down transistor, said transistor comprising:
a substrate;
a drain region in said substrate;
a source region in said substrate, said source region spaced from said drain region by a channel region and extended into a portion of said channel region;
a gate structure above said channel region; and
a spacer at a sidewall of said gate structure.

2. The transistor of claim 1, wherein said source region comprises a first region abutting a surface of said substrate and spaced from said channel region by said extended source region, wherein has dopant concentration different from other regions of said source region.

3. The transistor of claim 1, wherein said drain region comprises a second region abutting a surface of said substrate and adjacent to said channel region, wherein has dopant concentration different from said other regions of said drain region and is for reducing drain side sheet resistance.

4. The transistor of claim 1 further comprising:
a first lightly doped region lay under said source region and beside said channel region, said first lightly doped region having dopant concentration lighter than said source region doing; and
a second lightly doped region underlay said drain region and between said drain region and said channel region, said second lightly doped region having dopant concentration lighter than said drain region doing.

5. An asymmetric pull-down transistor, said transistor comprising:
a substrate of a first conductivity type;
a drain region of a second conductivity type in said substrate;
a source region of said second conductivity type in said substrate, said source region spaced from said drain region by a channel region and extended into a portion of said channel region;
a gate structure above said channel region;
a first lightly doped region of said second conductivity type lay under said source region and beside said channel region, said first lightly doped region having dopant concentration lighter than said source region doing; and
a second lightly doped region of said second conductivity type underlay said drain region and between said drain region and said channel region, said second lightly doped region having dopant concentration lighter than said drain region doing.

6. The transistor of claim 5, wherein said source region comprises a first region abutting a surface of said substrate and spaced from said channel region by said extended source region, wherein has dopant concentration different from other regions of said source region.

7. The transistor of claim 5, wherein said drain region comprises a second region abutting a surface of said substrate and adjacent to said channel region, wherein has dopant concentration different from said other regions of said drain region and is for reducing drain side sheet resistance.

8. The transistor of claim 5, wherein said first conductivity is opposite to said second conductivity.

9. A method for forming an asymmetric pull-down transistor, said method comprising:
providing a substrate of a first conductivity type;
forming a gate structure on said substrate wherein said substrate below said gate structure is used as a channel;
forming a mask for covering a first portion of said gate structure and a second portion of said substrate;
using said gate structure and said mask as implanting mask and tilted implanting a plurality of first ions of a second conductivity into said substrate to form a source region and a drain region wherein said source region is extended into a third portion of said channel;
removing said mask; and
forming a spacer at a sidewall of said gate structure.

10. The method according to claim 9 further comprising implanting a plurality of second ions of said second conductivity into said source region and said drain region to form a first region in said source region and a second region in said drain region.

11. The method according to claim 10, wherein said first region abuts a surface of said substrate and is spaced from said channel by said extended source region.

12. The method according to claim 10, wherein said second region abuts a surface of said substrate and is adjacent to said channel wherein has dopant concentration different from other portion of said drain region and is used for reducing drain side sheet resistance.

13. The method according to claim 9, wherein said step of implanting said first ions is implemented by intersecting and tilting incident direction vertical to a surface of substrate.

14. The method according to claim 9 further comprising implanting a plurality of third ions of said second conductivity into said substrate to form a first lightly doped region lay under said source region and a second lightly doped region underlay said drain region.

15. The method according to claim 14, wherein said second lightly region is between said drain region and said channel.
